(19) United States
(12) Patent Application Publication
(10) Pub. No.: US 2013/0082709 A1
(43) Pub. Date: Apr. 4, 2013

(54) PARALLEL MAGNETIC RESONANCE IMAGING USING GLOBAL VOLUME ARRAY COIL

(71) Applicants: Alan R. RATH, Fremont, CA (US); Wai Ha WONG, San Jose, CA (US); Weston A. ANDERSON, Palo Alto, CA (US)

(72) Inventors: Alan R. RATH, Fremont, CA (US); Wai Ha WONG, San Jose, CA (US); Weston A. ANDERSON, Palo Alto, CA (US)

(73) Assignee: AGILENT TECHNOLOGIES, INC., Loveland, CO (US)

(21) Appl. No.: 13/584,126

(22) Filed: Aug. 13, 2012

Related U.S. Application Data
(60) Provisional application No. 61/541,507, filed on Sep. 30, 2011.

(51) Int. Cl. G01R 33/48; G01R 33/341

(52) U.S. Cl. 324/310; 324/322

(57) ABSTRACT

A magnetic resonance imaging (MRI) apparatus comprises a plurality of cylindrical electromagnetic coils arranged in a coaxial configuration around a sample region. The coils are used to capture resonance signals from a sample at different times according to a geometric echo effect. The measurements can then be combined to produce an MRI signal.

### CROSS-REFERENCE TO RELATED APPLICATIONS

The present application claims priority under 35 U.S.C. §119(e) from U.S. Provisional Application No. 61/541,507, filed on Sep. 30, 2011. The entire disclosure of this provisional application is specifically incorporated herein by reference.

### BACKGROUND

A magnetic resonance imaging (MRI) machine uses a static magnetic field to align atomic dipoles in a sample (e.g., an organism or chemical compound) and then uses a dynamic magnetic field (e.g., radio frequency (RF) fields) to systematically perturb the alignment of the dipoles, causing them to produce a rotating magnetic field. The machine then measures the rotating magnetic field to construct an image of the sample.

The dynamic magnetic field is typically produced by electromagnetic coils located adjacent to the sample during MRI measurements. These coils can be referred to as excitation coils because they excite resonance in the sample. Similarly, the rotating magnetic fields are measured by electromagnetic coils located adjacent to the sample during MRI measurements. These coils can be referred to as measurement coils. In many MRI machines, excitation and measurement are performed by the same electromagnetic coils, so the terms excitation coil and measurement coil may refer to the same thing. Accordingly, for simplicity, electromagnetic coils used for excitation and/or measurement will be referred to by the general term “coils”.

In an effort to improve speed and accuracy, many MRI machines perform measurements using arrays of coils operating in parallel. The most common type of array is a surface array coil in which multiple coils are arranged adjacent to each other on a surface such as a blanket. These coils acquire measurements in parallel, and the measurements are then combined to form a composite image. These parallel measurements can be taken of different portions of a sample to improve imaging speed, or they can be taken of the same portion of a sample to provide redundant information for improved accuracy.

Common examples of MRI imaging techniques using a surface array coil include simultaneous acquisition of spatial harmonics (SMASH) and sensitivity encoding for fast MRI (SENSE). An example of a technique for combining parallel MRI measurements from a surface coil array is a technique referred to as generalized autocalibrating partially parallel acquisitions (GRAPPA). Each of these techniques has been used routinely in clinical settings.

Although surface array coils can improve the speed and accuracy of MRI measurements, they nevertheless suffer from various deficiencies. One deficiency is that the coils have shallow measurement depth, which means they have poor sensitivity to deeper portions of a sample. Another deficiency is that the coils have inhomogeneous sensitivity profiles, which leads to inconsistent measurements. An MRI machine can compensate for this lack of homogeneity by creating a complex calibration map for the coils, and then adjusting measurements according to the calibration map. However, this typically results in imaging artifacts due to imperfect calibration. Yet another deficiency is that the coils tend to be affected by noise in a coherent fashion because they perform measurements on the sample at the same time. This noise increases with the number of coils, so it can prevent accuracy from being improved through the use of additional coils.

What is needed therefore, are MRI machines capable of performing measurements at efficient speeds with improved sensitivity and accuracy.

### SUMMARY

In accordance with a representative embodiment, a method of operating a magnetic resonance imaging (MRI) apparatus comprising a plurality of cylindrical electromagnetic coils arranged in a coaxial configuration around a sample region and tuned to a common frequency is described. The method comprises applying a static magnetic field to a sample located, within the sample region to align nuclear dipoles of the sample, applying a perturbation signal to the sample using one of the coils, applying a field gradient to the sample along a center axis of the coils, and detecting resonance signals at the respective coils in succession according to a geometric echo effect determined by different electromagnetic profiles of the coils.

In accordance with another representative embodiment, a magnetic resonance imaging (MRI) apparatus, comprises first through third electromagnetic coils each having a cylindrical structure and arranged in a coaxial configuration around a sample region, and control circuitry configured to control the apparatus to apply a perturbation signal to the sample region through one of the coils, to subsequently apply a field gradient along a central axis of the first through third coils, and then to detect resonance signals at the other two coils at different successive times according to a geometric echo effect determined by different electromagnetic profiles of the first through third coils.

In accordance with another representative embodiment, a method of operating a global volume array coil comprising multiple electromagnetic coils arranged in a coaxial configuration and operating at a common frequency is described. The method comprises operating one of the coils to perturb a sample with a radio frequency (RF) signal and to detect a resonance signal, and operating the remaining coils to detect resonance signals at different times determined by different electromagnetic profiles of the electromagnetic coils.

### BRIEF DESCRIPTION OF THE DRAWINGS

The example embodiments are best understood from the following detailed description when read, with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a diagram of a global volume array coil comprising multiple concentric birdcage coils according to an example embodiment.

FIG. 2 is a diagram of a zero-th order mode birdcage coil according to an example embodiment.

FIG. 3 is a diagram of a first order mode birdcage coil according to an example embodiment.

FIG. 4 is a simplified diagram of the first order mode birdcage coil of FIG. 3 according to an example embodiment.

FIG. 5 is a waveform timing diagram illustrating a method of operating a global volume array coil to capture MRI measurements according to an example embodiment.

FIG. 6 is a flowchart illustrating a method of operating a global volume array coil to capture MRI measurements according to an example embodiment.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices. As used in the specification and appended claims, and in addition to their ordinary meanings, the terms ‘substantial’ or ‘substantially’ mean to within acceptable limits or degree. As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element.

The described embodiments relate generally to global volume array coils for MRI machines. Examples of such coils are disclosed in U.S. Pat. No. 6,420,871, the disclosure of which is hereby incorporated by reference in its entirety. The described embodiments provide methods of using such coils to improve the sensitivity and accuracy of MRI measurements.

In certain embodiments, a global volume array coil comprises multiple cylindrical coils of differing diameters arranged around a common axis. These coils can be, for example, birdcage coils, millipede coils, saddle coils, Alderman-Grant coils, or other types of coils. These coils can be designed to cover the entire field of view (FOV) of a sample being imaged. As more coils are used to image the sample, the sensitivity of the imaging increases. For example, in certain embodiments, the sensitivity of imaging improves by a factor of the square root of the number of coils used.

The global volume array coil has relatively high sensitivity to a middle portion of the sample because it has greater magnetic depth penetration compared with other types of coils, such as surface array coils. Due to this relatively high sensitivity, the global volume array coil can provide superior imaging compared other types of coils. Moreover, the use of multiple concentric coils also improves imaging sensitivity proportional to the square root of the number of coils used.

The global volume array coils are designed with geometries that isolate them electromagnetically from each other, which can reduce interference between the coils. Moreover, during operation, the coils detect MRI signals at slightly different times, so noise from the sample being imaged is not coherent in the measurements.

The described embodiments apply to MRI generally, so they can be used in nearly any type of MRI application, including for example, clinical procedures, industrial measurement technologies, research platforms, and so on. In addition, although certain embodiments are described with reference to a birdcage or millipede type volume array coil, the embodiments are not limited to these types of coils.

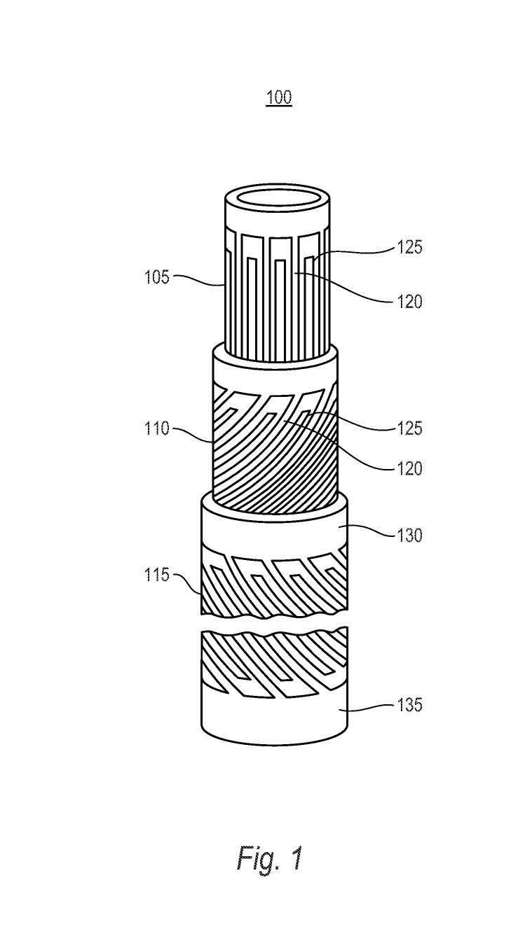

FIG. 1 is a diagram of a global volume array coil 100 comprising multiple concentric birdcage coils according to an example embodiment.

Referring to FIG. 1, global volume array coil 100 comprises first, second and third coils, 105, 110, 115 arranged coaxially inside one another and tuned to the same RF frequency. During operation, each coil is connected to an independent RF receiver, and one of the coils is also connected to an RF transmitter. The coil connected to the RF transmitter generates an excitation signal to perturb a sample, and ail three coils receive MRI signals in their RF receivers in response to resonances of the sample.

Although FIG. 1 shows these coils only partially inside one another, during operation they are arranged so that third coil 115 completely surrounds first and second coils 105 and 110, and second coil 110 completely surrounds first coil 105. Moreover, during operation, the upper and lower portions of each of these coils will be substantially aligned with each other to form an RF window extending from the top to the bottom of these coils.

Although first, second and third coils, 105, 110, 115 are shown as birdcage coils in FIG. 1, they could be substituted by other types of global volume array coils, such as millipede coils. In addition, in some embodiments, first, second and third coils, 105, 110, 115 are separated by a hollow cylindrically shaped insulator body. Such an insulator body can electrically insulate them one from another and also provide structural stability to global volume array coil 100.

Each of the first, second and third coils, 105, 110, 115 comprises two conductive rings that are separated, from each other along the central axis and a large number of conductive linearly elongated legs extending between the two conductive rings. For convenience of description, these two conductive rings will be referred to as an “upper ring” and a “lower ring”. For example, an upper ring 130 and a lower ring 135 are shown on third coil 115.

In each of the first, second and third coils, 105, 110, 115, conductive legs 120 extend from the upper ring towards the lower ring without reaching it, and conductive legs 125 extend from the lower ring towards the upper ring without reaching it. These legs are referred to as downward extending legs and upward extending legs, respectively. The downward and upward extending legs are arranged alternately around the rings, and they are spaced apart so they do not contact each other but are capacitively coupled.

First coil 105 can be referred to as a straight type birdcage coil because its legs extend parallel to the central axis. Alternatively, it can be referred to as a zero-th order mode (M=0) coil because its legs do not have any rotation about the central axis. The straight type birdcage coil generates a B1 field in a uniform direction between the upper ring and the lower ring. More specifically, the B1 field extends perpendicular to the central axis.

Second coil 110 and third coil 115 can be referred to as spiral type birdcage coils because their legs are helically twisted relative to the central axis. Alternatively, second coil 110 can be referred to as a first order mode (M=1) coil because its legs are twisted around the central axis by one (1) rotation in a positive direction (+360 degrees), and third coil 115 can be referred to as a negative first order mode (M=−1) coil because its legs are twisted around the central axis by one (1) rotation in a negative direction (−360 degrees).

Each of the spiral type birdcage coils generates a Bi field that rotates azimuthally around the central axis uniformly and by a specified angle (herein referred to as a “twist angle”) in a direction from the upper ring to the lower ring. The twist angle of second coil 110 is 360 degrees, and the twist angle of third coil 115 is −360 degrees. Near the upper ring, the B1 field of second coil 110 points in a first direction perpendicular to the central axis. It rotates about the central coil axis until it points in a direction opposite to the first direction halfway between the upper and lower rings, and it rotates until it again points in the same first direction when it is near the lower ring. The B1 field of third coil 115 similarly changes direction between the upper and lower rings but rotates in the opposite direction about the central axis.

Because the twist angle of the second coil 110 is 360 degrees and the direction of its B1 field rotates by 360 degrees azimuthally around, the central axis between the upper and lower rings, the total magnetic flux intercepted by the RF window between the two rings of first coil 105 will sum up to zero. In other words, the current that may be induced, in first coil 105 due to the driving of the second coil 110 will be zero. Stated yet another way, first coil 105 and second coil 110 are orthogonal, meaning that they have zero mutual inductance, or are inductively transparent to each other.

Similarly, third (outer) coil 115 is also orthogonal to both first coil 105 and second coil 110 because its twist angle of −360 degrees is different from those of the first coil 105 and the second coil 110 by integer multiples of 360 degrees. In sum, all three of the first coil 105, second coil 110 and third coil 115 of the coil structure of FIG. 1 are mutually orthogonal even though they are tuned to the same RF frequency.

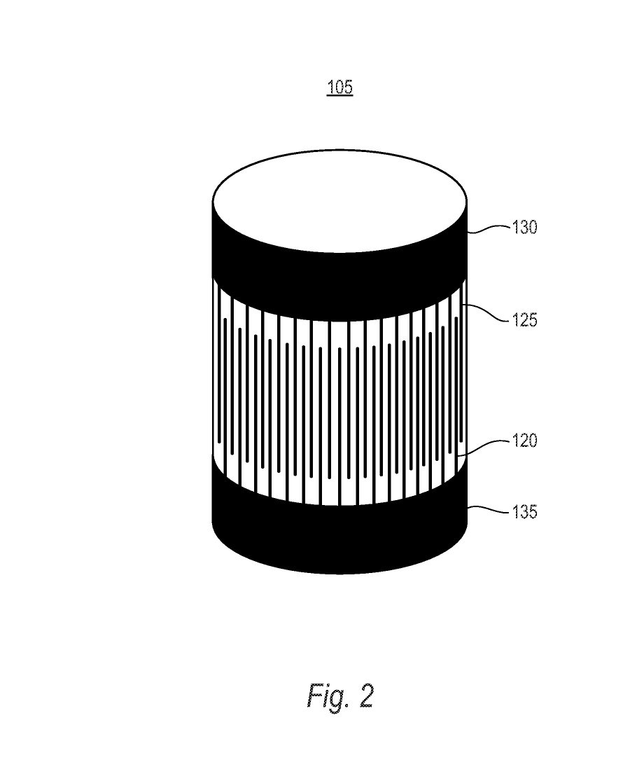

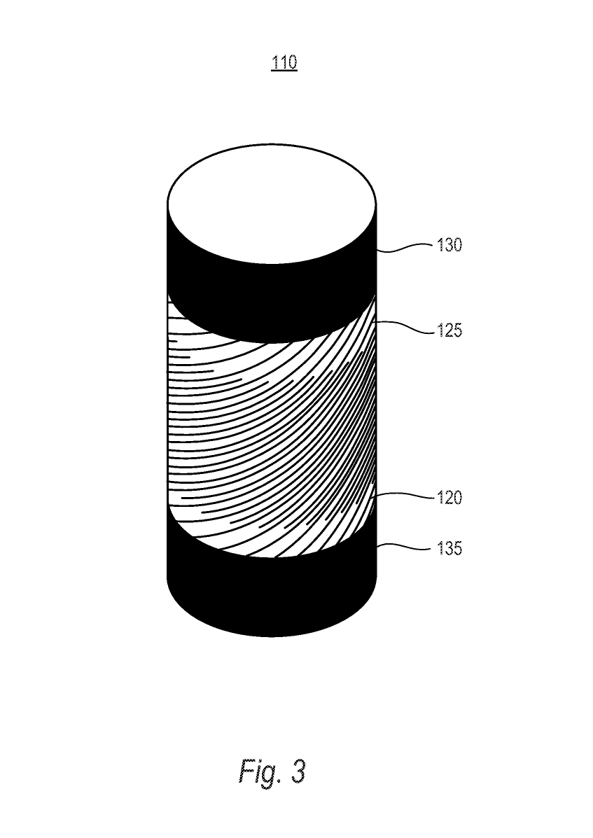

FIGS. 2 and 3 are diagrams illustrating examples of first coil 105 and second coil 110. In these examples, dark areas indicate conductive portions of the coils and the light areas indicate gaps or voids in the coils.

Referring to FIG. 2, first coil 105 comprises lower ring 135, upper ring 130, and conductive legs 120 and 125 extending from these respective rings. These conductive features are typically formed by etching a conductive laminate formed on a dielectric substrate. The substrate and the etched laminate are then rolled into a cylinder, which can be bonded together at its edges for stability. Once formed into a cylinder in this manner, first coil 105 can be placed inside second and third coils 110 and 115. Second, and third coils 110, 115 can be formed in a similar manner by etching a conductive laminate formed on a dielectric substrate and then rolling the substrate.

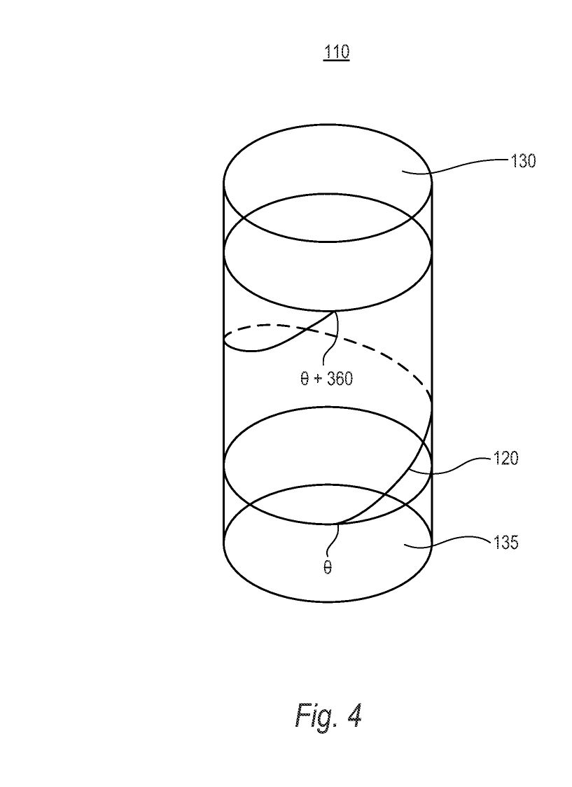

Referring to FIG. 3, second coil 110 comprises lower ring 135, upper ring 130, and conductive legs 120 and 125 extending from these respective rings, similar to first coil 105. However, unlike first coil 105, conductive legs 120 and 125 in second coil 110 are twisted relative to the central axis with a twist angle of 360°, as illustrated more particularly in FIG. 4.

FIG. 4 is a simplified diagram of second coil 110 according to an example embodiment. This diagram shows only one of conductive legs 120 in order to clearly illustrate the twist angle of 360 degrees.

Referring to FIG. 4, one of conductive legs 120 begins at an angle θ next to lower ring 135. As it extends toward upper ring 130, it rotates 360 degrees around a central axis until if arrives at an angle θ+360. It makes electrical contact with the lower ring but not the upper ring. Although not shown, conductive legs 125 can similarly rotate 360 degrees around the central axis as they extend from upper ring 130 toward lower ring 135. Conductive legs 125 make electrical contact with the upper ring 130, but not the lower ring 135.

Because conductive legs 120 make a single rotation about a central axis, second coil 110 is referred to as a first order mode (M−1) coil. In alternative embodiments, conductive legs 120 can make multiple integer rotations around the central axis. In general, conductive legs 120 can be formed with number of rotations, or even fractional rotations (e.g., 180 degrees) around the central axis. However, as the number of rotations increases, the length of conductive legs 120 increases accordingly, which increases their overall resistance and can reduce the sensitivity of the coil.

Although global volume array coil 100 is described above with three coaxial coils, it can be modified to include any number of coaxial coils. In general, increasing the number of coils can increase the number of parallel measurements obtained by global volume array coil 100, which can improve accuracy or sensitivity. However, increasing the number of coils also tends to increase the size of the outermost coil, which can result in very long conductive legs having high resistance and low sensitivity. Accordingly, there is a tradeoff between the number of coils and the sensitivity of global volume array coil 100.

In addition, although global volume array coil 100 is described above with coils having twist angles of 360 degrees, −360 degrees, and zero degrees, it can be modified to include coils with twist angles equal to other integer multiples of 360 degrees or fractions thereof, such as 180 degrees. In general, spiral birdcage coils with twist angles that differ from each other by integral multiples of 360 degrees are in principle orthogonal to each other.

In operation, a strong linear magnetic field gradient G_{Z} is applied to change the magnetic field configuration at the sample, thereby enabling the sample magnetization to be transferred from a first coil to a second coil, and then to a third coil. With a positive gradient G_{Z}, the field at the top of global volume array coil 100 is increased so the spin frequency increases slightly and the field at the bottom of global volume array coil 100 is slightly decreased so the spin frequency in this region decreases slightly. Applying 90 degree RF pulse to a coil with a given twist angle results in the spin magnetization of the sample that has the same twist angle. For example, applying an RF pulse to the third (outer) coil 115 of FIG. 1 results in an initial sample magnetization that has a twist angle of −360 degrees (M=−1). Then, by applying a positive gradient G_{Z} the magnetic field becomes slightly higher at the top of the sample, causing its magnetization to slowly advance compared to the magnetization at the bottom of the sample. Where the magnetization at the top and bottom of the sample point in the same direction, a signal is induced in first coil 105, called a geometric echo. The magnetization at the top of the sample continues its faster precession until the magnetization matches the configuration of second coil 110, thereby producing a geometric echo in this coil.

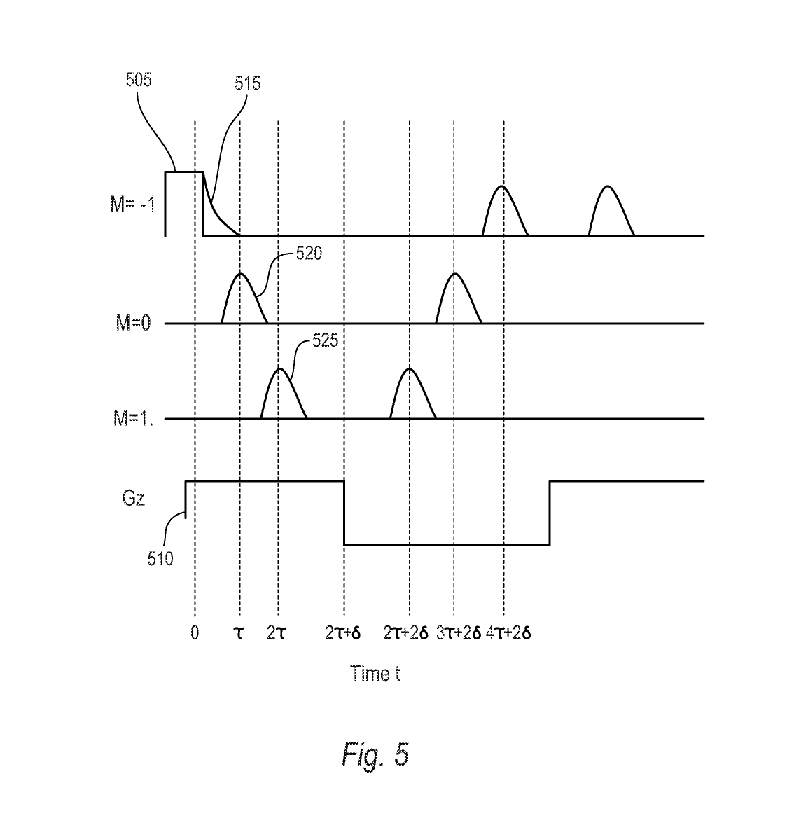

FIG. 5 is a waveform timing diagram illustrating this method of operating a global volume array coil to capture MRI measurements. In this example the third coil 115 with M=−1 is connected to an RF transmitter in order to apply an RF excitation signal to a sample being imaged, and each of third coil 115, first coil 105 and second coil 110 is connected to a corresponding RF receiver to receive MRI signals generated by the sample. These coils are ail tuned to the same RF frequency so they can obtain parallel MRI measurements of the sample.

In addition to the circuits and other components described herein, global volume array coil 100 may be driven or controlled by other features, as will be apparent to those skilled in the art with the benefit of this description.

In general, the method of FIG. 5 comprises a pulse, a gradient, and a data acquisition sequence. In this sequence, third coil 115 applies an RF pulse to the sample being imaged. Then, a gradient is applied to global volume array coil 100, and third coil 115, first coil 105 and second coil 110 detect MRI signals in succession. These MRI signals are generated at different times due to a geometric echo, as will be described below. Because the MRI signals are generated at different times, their noise profiles are not coherent, so the noise in these measurements can be averaged out. After the MRI signals are successively acquired by each of third coil 115, first coil 105 and second coil 110, the gradient is reversed, and MRI signals are successively received from these coils in a reverse order. A more specific description of the method is provided below.

Referring to FIG. 5, all of the nuclear spins in the sample are initially aligned with a static magnetic field along a z-direction parallel with the center axis of global volume array coil 100. Third coil 115 applies a 90 degree pulse 505 to the sample, causing the spins to flip by 90 degrees so they are perpendicular to the z-axis. Next, a constant z-gradient 510 is turned on so that the nuclear spins of atoms toward one end of global volume array coil 100 precess at a higher rate than nuclear spins at the other end of global volume array coil 100.

After the 90 degree pulse 505, third coil 115 senses a free induction decay (FID) signal 515 from the sample. Then, at successive times t=τ and t=2τ, first (inner) coil 105 and second (middle) coil 110 sense FID signals from the sample. The value of τ is determined by an equation τ=2π/(γG_{z}*FOV), in which γ represents the gyromagnetic ratio of the sample, G_{z} represents the magnitude of constant z-gradient 510, and FOV represents the length of the RF window of global volume array coil 100.

At t=τ, nuclear spins perpendicular to the z-direction have unwound so they all point in the same horizontal direction that is matched with the geometric wiring pattern of the first coil 105. When this happens, a maximum MRI signal 520 is detected by the first coil 105. At t=2τ, the nuclear spins perpendicular to the z-direction develop a global phase shift that is matched with the geometric wiring pattern of second coil 110. When this happens, a maximum MRI signal 525 is detected by second coil 110.

As further illustrated in FIG. 5, at a time t=2τ+δ, the direction of constant z-gradient 510 is reversed and the geometric echo appears at second coil 110 at a time t=2τ+2δ, then in first coil 105 at a time t=3τ+2δ, and finally in the second coil 110 at a time t=4τ+2δ. Thereafter, the gradient direction can be reversed again and the gradient echo sequence can be repeated.

As illustrated in FIG. 5, a three coil global volume array coil receives three times as many signals as a single coil within a single gradient cycle. These signals can be combined to generate MRI measurements with enhanced sensitivity and/or accuracy. Additionally, the geometric echoes arrive at different times at different coils, so their associated, sample noises are not coherent. Consequently, noise in those signals will tend, to average itself out when the detected signals are combined.

The method of FIG. 5 can be applied in situations where a local dephasing time T₂* without the gradient is significantly longer than the gradient dephasing time τ. This requirement is generally satisfied in most contexts of interest.

In the method of FIG. 5, first, second and third coils, 105, 110, 115 receive signals with different maximum signal strengths because these coils have different filling factors. However, in a sample noise dominated region, both the signal and noise from the sample are multiplied by the same filling factor. As a result, their ratio (i.e., the signal-to-noise ratio) is identical for each of the detection coils. By normalizing signals from three different coils to the same signal height, noises will be normalized automatically. Accordingly, a final measurement signal generated from the outputs of first, second and third coils, 105, 110 and 115 will be a simple sum of all the three outputs.

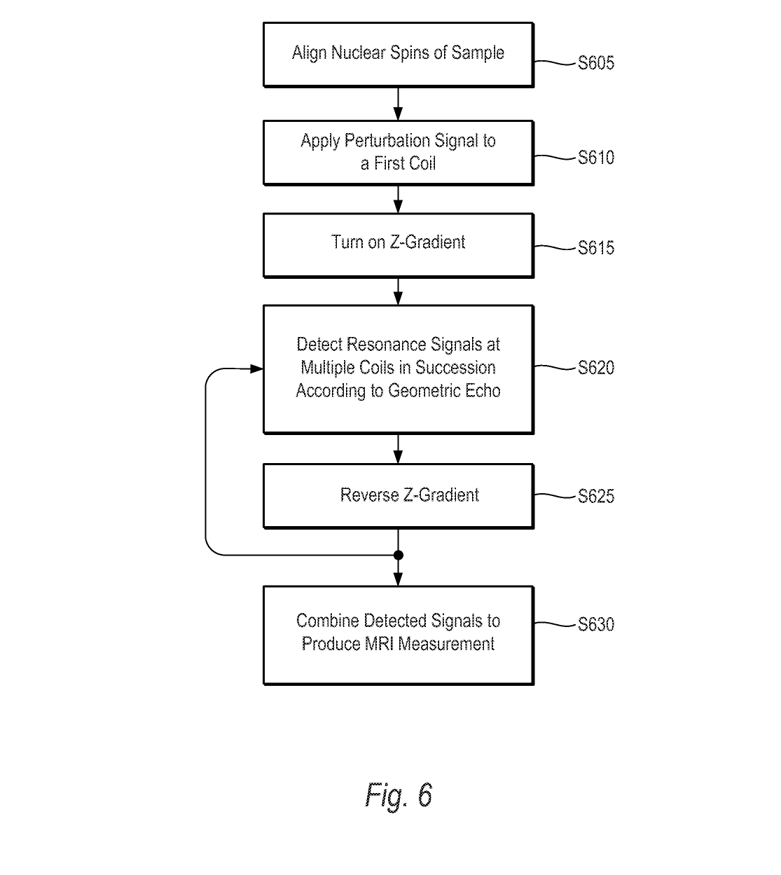

FIG. 6 is a flowchart illustrating a method of operating a global volume array coil to capture MRI measurements according to an example embodiment. This method is similar to that illustrated in FIG. 5, and it can be performed, using global volume array coil 100 or a similar structure.

Referring to FIG. 6, the method, begins by aligning the nuclear dipoles of atoms in a sample (S605). This is typically accomplished by applying a static magnetic field to the sample along a center axis of the global volume array coil. Next, the method applies a perturbation signal to a first coil of the global volume array coil (S610). The perturbation signal can be, for instance, the 90 degree pulse 505 explained with reference to FIG. 5. Thereafter, the method applies a gradient along the center axis of the global volume array coil (S615), which influences the rate of precession of nuclear spins in the sample along the center axis. Then, the method detects resonance signals at each of the multiple coils of the global volume array coil (S620). The timing of these signals is governed by the geometric echo as described above with reference to FIG. 5. In other words, a resonance signal is detected at a different time for each of the multiple coils according to the different electromagnetic profiles of the coils. For instance, a maximum signal value is detected by first coil 105 at time t=τ because at that instant, the respective phases of the precessing nuclear spins of the sample at top, middle, and bottom portions along the center axis are matched to the electromagnetic profile of first coil 105.

After a resonance signal has been detected for each of the individual coils in the global volume array coil, the z-gradient is reversed (S625) and additional signals are detected by each of the individual coils (S620).

After a number of signals are captured by the coils, the signals can be combined to form a MRI measurement (S630). The signals can be combined, for instance, by averaging or summing them. In addition, prior to summing or averaging the signals, they can be normalized as described above with reference to FIG. 5.

While example embodiments are disclosed herein, one of ordinary skill in the art appreciates that many variations that are in accordance with the present teachings are possible and. remain within the scope of the appended claims. The embodiments therefore are not to be restricted except within the scope of the appended claims.

As an example, a reverse sequence can be applied to global volume array coil 100 of FIG. 1. The reverse sequence is similar to the sequence described above in relation to FIG. 5, but with the gradient field G_{Z} reversed, i.e. using a negative gradient. In this case, a 90 degree RF pulse is applied to second coil 110 followed by applying the gradient—G_{Z}. After an FID signal on second coil 110, a geometric echo is produced on first coil 105 followed by geometric echo on the third (outer) coil 115.

An example of a spiral type bird cage coil array with four coils might consist of four individual concentric bird cage spiral coils with the following modes, M=−3/2, −1/2, +1/2, and +3/2. In this case a 90 degree RF pulse is applied, to the M=−3/2 coil followed by applying the gradient G_{Z}. After FID on the M=−3/2 coil, geometric echoes are produced sequentially on the coils with M=−1/2, 1/2, and 3/2.

The described embodiments are not limited, to these alternatives, as there are numerous array coils and various types of magnetic field gradients that can be used to produce the described geometric echoes.

1. A method of operating a magnetic resonance imaging (MRI) apparatus comprising a plurality of cylindrical electromagnetic coils arranged in a coaxial configuration around a sample region and tuned to a common frequency, the method comprising:
applying a static magnetic field to a sample located within the sample region to align nuclear dipoles of the sample;
applying a perturbation signal to the sample using one of the coils;
applying a field gradient to the sample along a center axis of the coils; and
detecting resonance signals at the respective coils in succession according to a geometric echo effect determined by different electromagnetic profiles of the coils.

2. The method of claim 1, wherein the coils detect the resonance signals at different times separated by an interval τ=2π/(γG₂*FOV), where γ represents a gyromagnetic ratio of the sample, G_{z} represents a magnitude of the field gradient, and FOV represents a length of a radio frequency (RF) window of the coils.

3. The method of claim 1, wherein the coils are inductively isolated with respect to each other according to their respective geometries.

4. The method of claim 1, wherein the coils are birdcage coils or millipede coils.

5. The method of claim 4, wherein a first one of the coils is a straight type birdcage coil, a second one of the coils is a spiral type birdcage coil with a twist angle of 360 degrees, and a third one of the coils is a spiral type birdcage coil with a twist angle of negative 360 degrees.

6. The method of claim 4, wherein the coils comprise four spiral type birdcage coils with respective twist angles of −540, −180, 180, and 540 degrees.

7. The method of claim 1, further comprising combining the resonance signals detected by the respective coils to generate an MRI measurement.

8. The method of claim 7, wherein combining the resonance signals comprises normalizing and then summing the resonance signals.

9. The method of claim 1, further comprising reversing the field gradient and detecting additional resonance signals at the coils in succession.

10. A magnetic resonance imaging (MRI) apparatus, comprising:
first through third, electromagnetic coils each having a cylindrical structure and arranged in a coaxial configuration around a sample region; and
control circuitry configured to control the apparatus to apply a perturbation signal to the sample region through one of the first through third, electromagnetic coils, to subsequently apply a field gradient along a central axis of the first through third coils, and then to detect resonance signals at the other two electromagnetic coils at different successive times according to a geometric echo effect determined by different electromagnetic profiles of the first through third coils.

11. The MRI apparatus of claim 10, wherein the first through third coils are configured to operate at the same frequency.

12. The MRI apparatus of claim 10, wherein the first coil comprises a straight type birdcage coil and the second and third coils are spiral type birdcage coils.

13. The MRI apparatus of claim 10, wherein the first through third coils are inductively transparent with respect to each other.

14. The MRI apparatus of claim 10, wherein the first through third coils each comprise an etched conductor formed on a dielectric substrate.

15. The MRI apparatus of claim 10, wherein the first through third coils have the same height and are aligned to form a common radio frequency window.

16. The MRI apparatus of claim 10, wherein the first coil is located inside the second and third coils, and
wherein the first coil is a zero-th order mode coil, the second coil is a first order mode coil, and the third, coil is a negative first order mode coil.

17. A method of operating a global volume array coil comprising multiple electromagnetic coils arranged in a coaxial configuration and operating at a common frequency, the method comprising:
operating one of the coils to perturb a sample with a radio frequency (RF) signal and to detect a resonance signal; and
operating the remaining coils to detect resonance signals at different times determined by different electromagnetic profiles of the electromagnetic coils.

18. The method of claim 17, wherein the resonance signals are generated according to a geometric echo effect.

19. The method of claim 17, wherein the electromagnetic coils have different twist angles with respect to each other.

20. The method of claim 17, further comprising:
applying a field gradient along a central axis of the electromagnetic coils while operating the coils to detect the resonance signals at different times.
